(19) United States
(12) Patent Application Publication
(10) Pub. No.: US 2008/0105300 A1
(43) Pub. Date: May 8, 2008

(54) Solar cell and method for manufacturing photo-electrochemical layer thereof

(75) Inventors: Hung-Chang Chen, Tu-Chen City (TW); Wen-Ting Lin, Caotun Township (TW); Wen-Hsien Ho, Keelung City (TW); Masakazu Anpo, Izumisano-City (JP)

Correspondence Address: Robert F. Gazdzinski, Esq.;Gazdzinski & Associates, Suite 375, 11440 West Bernardo Court, San Diego, CA, 92127, US

(73) Assignee: TAIWAN TEXTILE RESEARCH INSTITUTE, Taipei Hsien (TW)

(21) Appl. No.: 11/648,432

(22) Filed: Dec. 28, 2006

(30) Foreign Application Priority Data
Nov. 6, 2006 (TW) 95141028

(51) Int. Cl. H01L 31/04

(52) U.S. Cl. 136/256; 216/24

(57) ABSTRACT

A solar cell includes a pair of electrodes, an electrolyte and a titanium dioxide layer. The electrolyte is positioned between the electrodes. The titanium dioxide layer is positioned between one of the electrodes and the electrolyte. Furthermore, the titanium dioxide layer has a rough surface opposite the electrolyte, and a range of ratios of oxygen ions to titanium ions is about 2˜1.9 in the titanium dioxide layer.

### RELATED APPLICATIONS

This application claims priority to Taiwan Application Serial Number 95141028, filed Nov. 6, 2006, which is herein incorporated by reference.

### BACKGROUND

1. Field of Invention

The present invention relates to an electrical current producing apparatus. More particularly, the present invention relates to an electrical current producing apparatus responsive to light.

2. Description of Related Art

As world populations grow and more third world countries start large economic developments, people need more and more energy than before. After energy crisis, people are subject to a dearth of energy. Therefore, many countries begin seeking replacement energy or new energy resources. Solar energy is one of the replacement energy or the new energy resources.

In 1970s, Bell Labs produce silicone solar cells to start development of commercial solar cells. This silicone solar cells convert photons from the sun (solar light) into electricity using electrons. This conversion is called the photovoltaic effect, and the field of research related to solar cells is known as photovoltaics. Although the efficiency of silicone solar cells (made of single crystal silicone) is 12%˜15%, the silicone solar cells are difficult to be manufactured and expensive. Therefore, the silicone solar cells are not available to all.

Accordingly, dye-sensitized solar cells are developed to solve the above mentioned problems. However, the efficiency of the dye-sensitized solar cells is still insufficient. Therefore, how to improve the efficiency of the dye-sensitized solar cells responsive to visible light is a serious challenge for many researchers.

### SUMMARY

According to one embodiment of the present invention, a solar cell includes a pair of electrodes, an electrolyte and a titanium dioxide layer. The electrolyte is positioned between the electrodes. The titanium dioxide layer is positioned between one of the electrodes and the electrolyte. Furthermore, the titanium dioxide layer has a rough surface opposite the electrolyte, and a range of ratios of oxygen ions to titanium ions is about 2˜1.9 in the titanium dioxide layer.

According to another embodiment of the present invention, a method for manufacturing a photo-electrochemical layer includes the following steps: A conducting substrate is provided. Then, a titanium dioxide layer is formed on a part of the conducting substrate by a sputtering process.

According to further another embodiment of the present invention, a method for manufacturing a photo-electrochemical layer includes the following steps: A conducting substrate is provided. Then, a titanium dioxide layer is formed on a part of the conducting substrate. Next, the titanium dioxide layer is etched.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a sectional view of a solar cell according to one embodiment of the present invention;

FIG. 2 is a secondary ion mass spectra graph of the titanium dioxide layer of FIG. 1;

FIG. 3 is a scanning electron microscope image of the rough surface of the titanium dioxide layer of FIG. 1;

FIG. 4 is a scanning electron microscope image of the titanium dioxide layer which has been etched by the wet etching process;

FIG. 5 is a graph of voltage versus current density for photo-electrochemical layers produced by different parameters of the sputtering process and a conventional titanium dioxide layer;

FIG. 6A and FIG. 6B are graphs of wavelength versus photo-current for photo-electrochemical layers;

FIG. 7A is a graph of potential versus photo-current for photo-electrochemical layers which has been etched for different times; and

FIG. 7B is a graph of etching time versus photo-current for photo-electrochemical layers.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

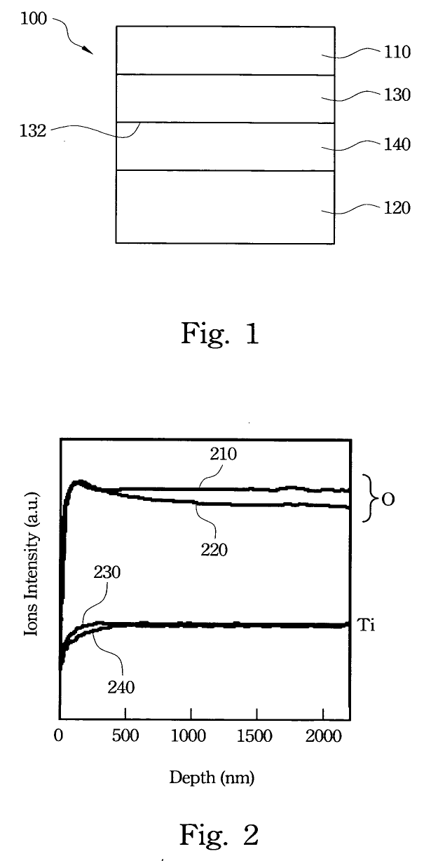

Reference is made to FIG. 1. FIG. 1 is a sectional view of a solar cell according to one embodiment of the present invention. As shown in FIG. 1, a solar cell includes a pair of electrodes 110/120, an electrolyte 140 and a titanium dioxide layer 130. The electrolyte 140 is positioned between the electrodes 110/120. The titanium dioxide layer 130 is positioned between the electrode 110 and the electrolyte 140. Furthermore, the titanium dioxide layer 130 has a rough surface 132 opposite the electrolyte 140, and a range of ratios of oxygen ions to titanium ions is about 2˜1.9 in the titanium dioxide layer 130.

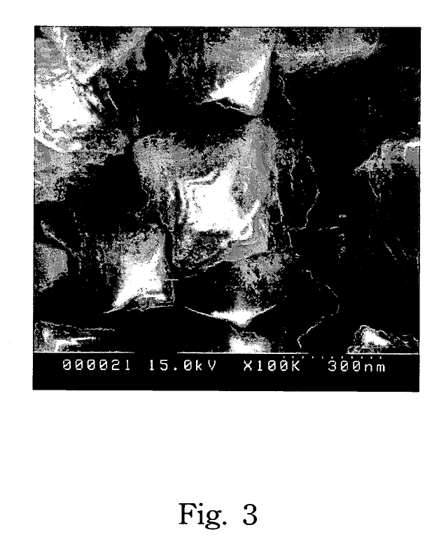

Reference is made to FIG. 2. FIG. 2 is a secondary ion mass spectra graph of the titanium dioxide layer 130 of FIG. 1. In FIG. 2, curves 210/240 respectively show oxygen ions and titanium ions in a conventional titanium dioxide layer. Curves 220/230 respectively show oxygen ions and titanium ions in the titanium dioxide layer 130 of FIG. 1. The conventional titanium dioxide layer is formed by sintering or a sol-gel process. The titanium dioxide layer 130 of FIG. 1 may be formed by sputtering. As shown in FIG. 2, the ratios of the oxygen ions to the titanium ions are decreased from the rough surface of the titanium dioxide layer 130 of FIG. 1 to the inside of the titanium dioxide layer 130 of FIG. 1. Compared with the conventional titanium dioxide layer, the oxygen ions in the titanium dioxide layer 130 of FIG. 1 are insufficient. Accordingly, the titanium dioxide layer 130 of FIG. 1 has a low energy band gap such that the titanium dioxide layer 130 of FIG. 1 can be responsive to visible light.

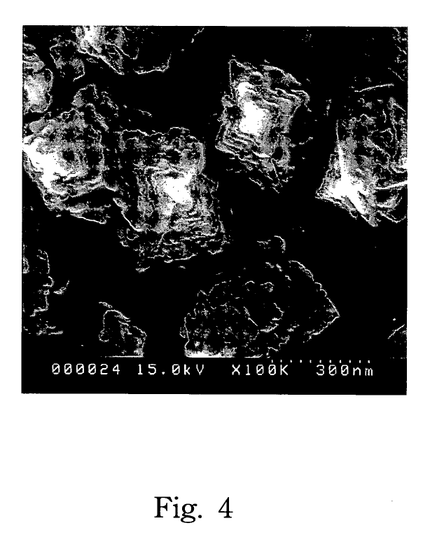

Reference is made to FIG. 3. FIG. 3 is a scanning electron microscope image of the rough surface 132 of the titanium dioxide layer 130 of FIG. 1. As shown in FIG. 3, the rough surface 132 of the titanium dioxide layer 130 of FIG. 1 may have a plurality of grains positioned thereon, and each of the grains may be pyramid shaped.

In this embodiment, the thickness of the titanium dioxide layer 130 may be about 0.5˜1.5 μm. Furthermore, the titanium dioxide layer 130 may not need to be doped with any impurities. However, the above mentioned parameters are only examples. In fact, the thickness of the titanium dioxide layer and whether the titanium dioxide layer is doped should depend on practical requirements.

Another embodiment of the present invention is a method for manufacturing a photo-electrochemical layer. The method includes the following steps: A conducting substrate is provided. Then, a titanium dioxide layer is formed on a part of the conducting substrate by a sputtering process. In the titanium dioxide layer formed by sputtering, a range of ratios of oxygen ions to titanium ions is about 2˜1.9. Accordingly, the titanium dioxide layer formed by sputtering has a lower energy band gap than conventional titanium dioxide layers do such that the titanium dioxide layer formed by sputtering can be responsive to visible light.

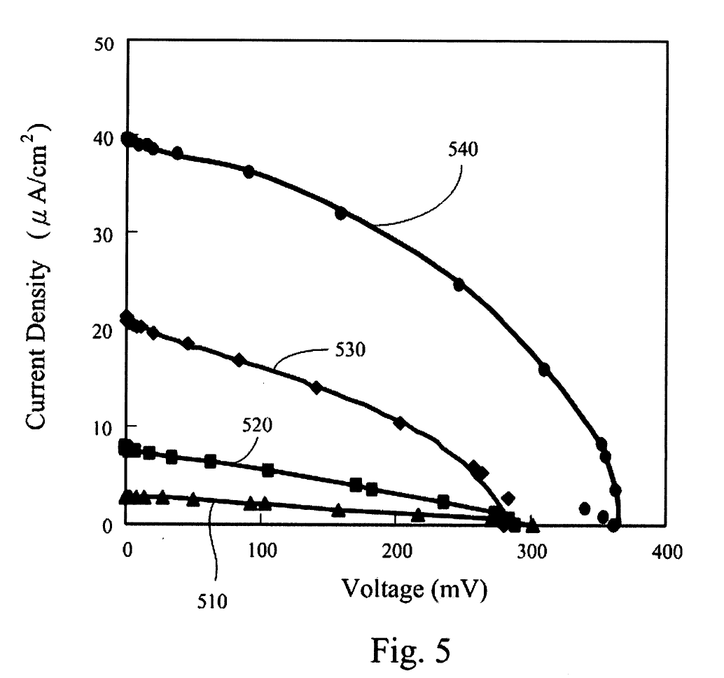

After the titanium dioxide layer is formed, the titanium dioxide layer may be etched to enhance the surface roughness of the titanium dioxide layer, thereby the efficiency of the photo-electrochemical layer is raised as well. The titanium dioxide layer may be etched by a wet etching process. Reference is made to FIG. 4. FIG. 4 is a scanning electron microscope image of the titanium dioxide layer which has been etched by the wet etching process. As shown in FIG. 4, the titanium dioxide layer which has been etched by the wet etching process does not only have pyramid shaped grains positioned thereon, but each of the grains also has grooves positioned thereon. In other words, the wet etching process indeed enhances the surface roughness of the titanium dioxide layer.

In this embodiment, the reaction gas of the sputtering process may be argon or combination of both argon and oxide. The pressure of the reaction gas of the sputtering process may be about 1˜10 Pa. The temperature of the conducting substrate may be about 400˜600 K during the sputtering process. The reaction time of the sputtering process may be about 60˜120 minutes. The above mentioned parameters of the sputtering process are only examples, and the possibility of choice need not be limited to them. In fact, the parameters of the sputtering process should depend on practical requirements.

In yet another embodiment of the present invention, the titanium dioxide layer may be formed by other methods, e.g. sintering or a sol-gel process. Then, the titanium dioxide layer may be etched to enhance the surface roughness of the titanium dioxide layer such that the efficiency of the photo-electrochemical layer responsive to visible light can be raised.

In this embodiment, the titanium dioxide layer may be etched by a wet etching process. The etching solution of the wet etching process may be an aqueous solution of hydrofluoric acid. The concentration of the hydrofluoric acid in the aqueous solution may be about 0.1˜0.01 wt. %. The reaction time of the wet etching process may be about 15˜180 minutes. Similarly, the above mentioned parameters of the wet etching process are only examples, and the possibility of choice need not be limited to them. In fact, the parameters of the wet etching process should depend on practical requirements.

According to the embodiments of the present invention mentioned above, some examples are given thereinafter.

### EXAMPLE I

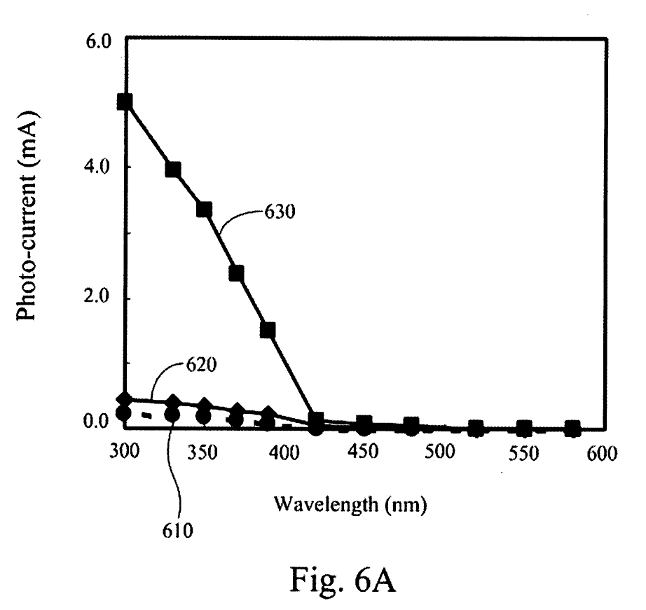

Reference is made to FIG. 5. FIG. 5 is a graph of voltage versus current density at a wavelength of more than 300 nm for photo-electrochemical layer produced by different parameters of the sputtering process and a conventional titanium dioxide layer. As shown in FIG. 5, a voltage versus current density curve 510 is for the conventional titanium dioxide layer. Another voltage versus current density curve 520 is for a photo-electrochemical layer produced by a sputtering process whose reaction temperature (the temperature of the conducting substrate during the sputtering process) is 673 K and whose reaction gas is argon. Still another voltage versus current density curve 530 is for another photo-electrochemical layer produced by another sputtering process whose reaction temperature is 873 K and whose reaction gas is argon. Yet another voltage versus current density curve 540 is for still another photo-electrochemical layer produced by still another sputtering process whose reaction temperature is 873 K and whose reaction gas is combination of both argon and oxide. FIG. 5 shows that the photo-electrochemical layers produced by the sputtering process have higher efficiency than the conventional titanium dioxide layer does, no matter what the reaction gas and the reaction temperature of the sputtering process is. Particularly, the photo-electrochemical layer produced by the sputtering process whose reaction gas is argon or combination of both argon and oxide has higher efficiency than the conventional titanium dioxide layer does.

### EXAMPLE II

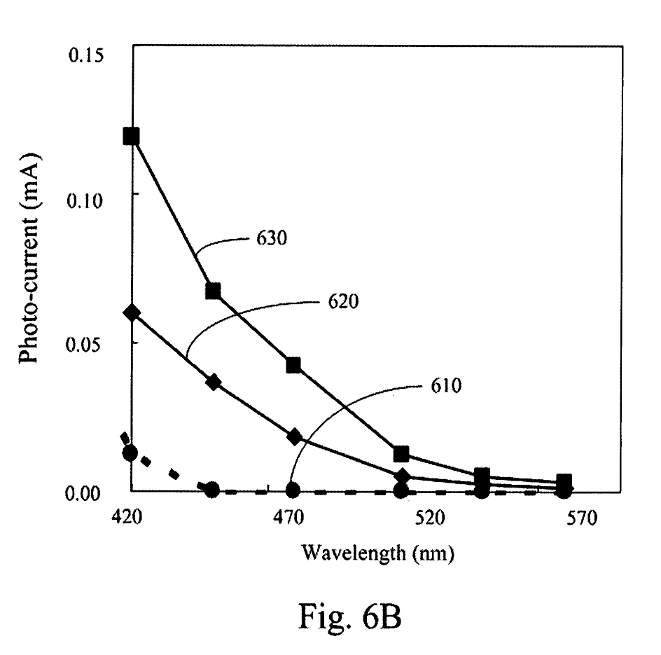

Reference is made to FIG. 6A and FIG. 6B. FIG. 6A and FIG. 6B are graphs of wavelength versus photo-current for photo-electrochemical layers. As shown in FIG. 6A and FIG. 6B, a wavelength versus photo-current curve 610 is for a conventional titanium dioxide layer. Another wavelength versus photo-current curve 620 is for a photo-electrochemical layer formed by the following steps:

(1) A part of a conducting glass is covered with tinfoil.

(2) The conducting glass is fixed on a substrate.

(3) The substrate is put into a chamber, and the pressure of the chamber is then controlled to 10⁻⁴ Pa.

(5) Argon is introduced with a pressure of 2 Pa in 25 s.c.c.m. for 20 minutes in order to remove contaminations on the surface of substrates.

(6) A titanium dioxide layer is formed on the conducting glass by a sputtering process, wherein the rotating speed of the sputtering process is 5 rpm, the power of the sputtering process is 300 W, the input DC voltage of the sputtering process is −0.45 kV, the reaction temperature of the sputtering process is 873 K and a distance between a target and the substrate during the sputtering process is set at 75 mm.

(7) The sputtering process operates for 90 minutes, and the chamber is cooled to less than 100° C.

(8) The conducting glass with the titanium dioxide layer (called the photo-electrochemical layer) is taken out, wherein the thickness of the titanium dioxide layer is 1˜3 μm.

Furthermore, still another wavelength versus photo-current curve 630 is for another photo-electrochemical layer which has been etched. Particularly, this photo-electrochemical layer is formed by the above mentioned steps (1)-(7), and the photo-electrochemical layer is then etched by an aqueous solution of 0.045 wt. % hydrofluoric acid for 120 minutes. FIG. 6A and FIG. 6B show that the photo-electrochemical layers formed by a sputtering process produce more photo-current than the conventional titanium dioxide layer does at a wavelength of 420 nm, whether the photo-electrochemical layers are etched. Particularly, the incident photon-to-current conversion efficiency (IPCE) of the photo-electrochemical layer which has been etched at a wavelength of 360 nm can be raised to 61%. The IPCE can be obtained by the following formula:

IPCE(%)=[1240×photo-current density(μA×cm⁻²)]/[wavelength(nm)×photonflux(μW×cm-2)]

### EXAMPLE III

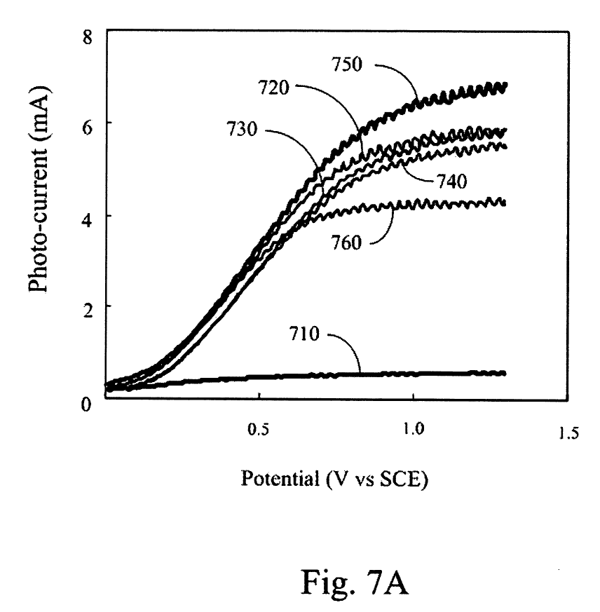

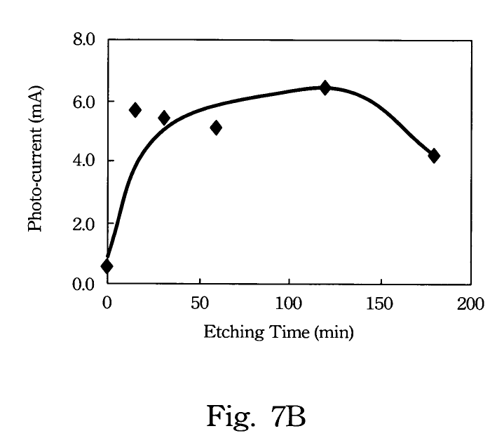

Reference is made to FIG. 7A and FIG. 7B. FIG. 7A is a graph of potential versus photo-current for photo-electrochemical layers etched for different times. FIG. 7B is a graph of etching time versus photo-current for photo-electrochemical layers. In FIG. 7A, a potential versus photo-current curve 710 is for a photo-electrochemical layer without being etched, another potential versus photo-current curve 720 is for another photo-electrochemical layer which has been etched by hydrofluoric acid for 15 minutes, still another potential versus photo-current curve 730 is for still another photo-electrochemical layer which has been etched by hydrofluoric acid for 30 minutes, yet another potential versus photo-current curve 740 is for yet another photo-electrochemical layer which has been etched by hydrofluoric acid for 60 minutes, still another potential versus photo-current curve 750 is for still another photo-electrochemical layer which has been etched by hydrofluoric acid for 120 minutes, and yet another potential versus photo-current curve 760 is for yet another photo-electrochemical layer which has been etched by hydrofluoric acid for 180 minutes. The data shown in FIG. 7A and FIG. 7B is obtained by irradiating the photo-electrochemical layers under a wavelength more than 300 nm. FIG. 7A and FIG. 7B show that the efficiency of the photo-electrochemical layers may not be raised as the etching time increases. In this example II, the photo-electrochemical layer which has been etched for 120 minutes has highest efficiency than other photo-electrochemical layers do.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

1. A solar cell, comprising:
a pair of electrodes;
an electrolyte positioned between the electrodes; and
a titanium dioxide layer positioned between one of the electrodes and the electrolyte, wherein the titanium dioxide layer has a rough surface opposite the electrolyte, and a range of ratios of oxygen ions to titanium ions is about 2˜1.9 in the titanium dioxide layer.

2. The solar cell of claim 1, wherein the ratios of the oxygen ions to the titanium ions are decreased from the rough surface of the titanium dioxide layer to the inside of the titanium dioxide layer.

3. The solar cell of claim 1, wherein the rough surface of the titanium dioxide layer has a plurality of grains positioned thereon, and each of the grains is pyramid shaped.

4. The solar cell of claim 1, wherein the thickness of the titanium dioxide layer is about 0.5˜1.5 μm.

5. The solar cell of claim 1, wherein the titanium dioxide layer is not doped with impurities.

6. A method for manufacturing a photo-electrochemical layer, comprising the steps of:
providing a conducting substrate; and
forming a titanium dioxide layer on at least a part of the conducting substrate by a sputtering process.

7. The method of claim 6, further comprising:
etching the titanium dioxide layer.

8. The method of claim 6, further comprising:
wet etching the titanium dioxide layer.

9. The method of claim 6, wherein the reaction gas of the sputtering process is argon or combination of both argon and oxide.

10. The method of claim 6, wherein the pressure of the reaction gas of the sputtering process is about 1˜10 Pa.

11. The method of claim 6, wherein the temperature of the conducting substrate is about 400˜600°C. during the sputtering process.

12. The method of claim 6, wherein the reaction time of the sputtering process is about 60˜120 minutes.

13. A method for manufacturing a photo-electrochemical layer, comprising the steps of:
providing a conducting substrate;
forming a titanium dioxide layer on at least a part of the conducting substrate; and
etching the titanium dioxide layer.

14. The method of claim 13, wherein the titanium dioxide layer is formed by a sputtering process.

15. The method of claim 13, wherein the titanium dioxide layer is etched by a wet etching process.

16. The method of claim 15, wherein the etching solution of the wet etching process is an aqueous solution of hydrofluoric acid.

17. The method of claim 16, wherein the concentration of the hydrofluoric acid in the aqueous solution is about 0.1˜0.01 wt. %.

18. The method of claim 17, wherein the reaction time of the wet etching process is about 15˜180 minutes.
